(19) United States
(12) Patent Application Publication
(10) Pub. No.: US 2006/0115750 A1
(43) Pub. Date: Jun. 1, 2006

(54) Film for color compensation, multi-functional film for color compensation and near infrared absorption and plasma display panel filter comprising the same

(76) Inventors: Su-rim Lee, Daejeon (KR); Sang-hyun Park, Daejeon (KR); In-seok Hwang, Daejeon (KR); Yeon-keun Lee, Daejeon (KR); Hyun-seok Choi, Daejeon (KR); Jung-doo Kim, Daejeon (KR); Dong-wook Lee, Daejeon (KR); Dmitry Grudinin, Daejeon (KR)

Correspondence Address: MCKENNA LONG & ALDRIDGE LLP, 1900 K STREET, NW, WASHINGTON, DC, 20006, US

(21) Appl. No.: 11/256,095

(22) Filed: Oct. 24, 2005

(30) Foreign Application Priority Data
Nov. 29, 2004 (KR) 10-2004-0098507

(51) Int. Cl. G03F 1/00

(52) U.S. Cl. 430/7

(57) ABSTRACT

The present invention relates to a film for color compensation and a multi-functional film for color compensation and near IR absorption for a PDP filter comprising a cyanine dye represented by the formula 1 below and a plasma display panel filter comprising the same: 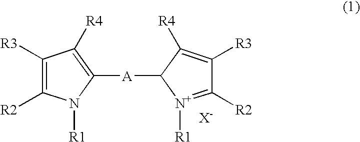 where definition of R1 to R4 and A are given in the specification. The film for color compensation and the multi-functional film for color compensation and near IR absorption of the present invention selectively absorbs light in the 560-600 nm region, can improve film durability and can improve contrast and color saturation of PDP images.

This application claims the benefit of the filing date of Korean Patent Application No. 10-2004-0098507 filed on Nov. 29, 2004 in the Korean Intellectual Property Office, the disclosure of which is incorporated herein in its entirety by reference.

### TECHNICAL FIELD

The present invention relates to a film for color compensation and a multi-functional film for color compensation and near IR absorption for a PDP filter comprising a cyanine dye represented by the formula 1 below and a PDP (plasma display panel) filter comprising the same:

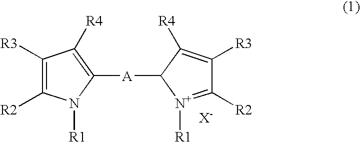

where definition of R1 to R4 and A are given in the specification.

### BACKGROUND ART

A PDP filter compensates decrease of purity of red spectrum by the specific orange spectrum emitted from a PDP and shields near infrared (hereunder referred to as “IR”) ray, which causes malfunction of remote controller devices, and electromagnetic interference, which is harmful to human body. For this purpose, a PDP filter comprises such functional layers as anti-reflection layer, color compensation layer, near IR absorption layer and electromagnetic interference shielding layer. Typically, each of these functional layers is in the form of film and is laminated using an adhesive.

Particularly for a film for color compensation, properties of neon-cut dye is very important, besides the dyes compensating for the primary colors of red (R), green (G) and blue (B). A neon-cut dye should have a maximum absorption wavelength in the range of 560-600 nm, so that it can shield the specific orange spectrum at 590 nm, which is generated as the excited neon atom goes back to the ground state in a PDP. Also, it should have a half absorption bandwidth not larger than 50 nm. In case a film is prepared by coating on a transparent substrate, the neon-cut dye should be fairly soluble in an organic solvent. Also, it should have a good thermal durability after a film is completed. And, in case a multi-functional film for color compensation and near IR absorption is prepared by coating the neon-cut dye along with a near IR absorbing dye on a substrate, it should have good compatibility with the dye.

However, a neon-cut dye prepared by the conventional method hasn't maximum absorption wavelength in the range of 560-600 nm and has a broad half bandwidth, thereby not effectively shielding the orange spectrum caused by the neon light emission, emits fluorescence, thereby reducing contrast and color saturation of PDP images, and does not offer sufficient thermal durability to the resultant film.

For example, US 2003/0165640 and JP 2004-99711 disclosed asymmetric cyanine dyes prepared by a series of synthesis processes in order to satisfy the absorption wavelength requirement. But, they do not mention thermal durability. JP 2003-36033 formed a metal-dye complex to satisfy the thermal durability requirement. However, it requires several synthesis steps, thereby increasing manufacture cost, and gives a low molar extinction coefficient, thereby requiring addition of a lot of dye to attain wanted cutting efficiency.

### DISCLOSURE OF INVENTION

The present inventors worked hard to solve these problems. In doing so, they found that when a film for color compensation and a multi-functional film for color compensation and near IR absorption are manufactured by using a cyanine dye comprising the pyrrole derivative represented by the formula 1, they have sufficient absorption ability at the selected wavelength, can improve contrast and color saturation of PDP images and can have improved thermal durability.

Accordingly, it is an object of the present invention to provide a film for color compensation and a multi-functional film for color compensation and near IR absorption for a PDP filter comprising the cyanine dye represented by the formula 1 below and a PDP filter comprising the films.

Hereunder is given a detailed description of the present invention.

The present invention relates to a film for color compensation for a PDP filter comprising the cyanine dye comprising a pyrrole derivative, which is represented by the formula 1 below.

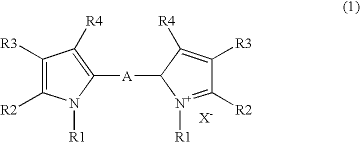

where

—A— represents a conjugated double bonding group having odd number of carbon atoms, for example,

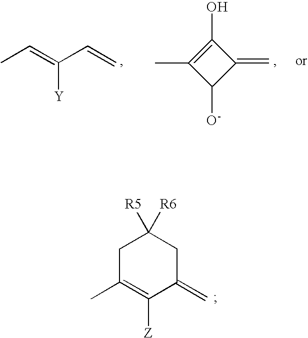

R1 represents a hydrogen atom, an aryl group optionally having substituent(s), an alkyl group optionally having substituent(s), an aryl group optionally having substituent(s), an aralkyl group optionally having substituent(s), an alkoxy group optionally having substituent(s), an aryloxy group optionally having substituent(s) or an alkoxycarbonyl group optionally having substituent(s);

each of R2-R4 represents a hydrogen atom, an alkyl group optionally having substituent(s), an alkenyl group optionally having substituent(s), an alkoxycarbonyl group optionally having substituent(s), a phenyl group optionally having substituent(s), a halogen atom, a nitro group, a cyano group, a hydroxy group, an amino group, a sulfonate group, a sulfonyl group or a carboxyl group;

each of R5 and R6 represents a hydrogen atom, a halogen atom, a cyano group, an aryl group optionally having substituent(s), a diphenylamino group or an alkyl group optionally having substituent(s);

each of Y and Z represents a hydrogen atom, a halogen atom, a cyano group or a C₁-C₈ alkyl group or a C₆-C₃₀ aryl group optionally having substituent(s); and

X⁻ represents a halide such as chloride, bromide, iodide and fluoride; a perhalogenate such as perchlorate, perbromate and periodate; a fluoro complex anion such as tetrafluoroborate, hexafluoroantimonate and hexafluorophosphate; an alkyl sulfate such as methyl sulfate and ethyl sulfate; or a sulfonate such as p-toluenesulfonate and p-chlorobenzenesulfonate.

In the definition of the substituent R1, the alkyl group optionally having substituent(s) refers to a C₁-C₂₀ linear or branched hydrocarbon group, such as methyl, ethyl, propyl, isopropyl, butyl, isobutyl, s-butyl, t-butyl, pentyl, isopentyl, neopentyl, t-pentyl, 1-methylpentyl, 2-methylpentyl, hexyl, cyclohexyl, isohexyl, 5-methylhexyl, 2-cyclohexylethyl, heptyl, isoheptyl, octyl, isoctyl, 3-octyl, 2-ethylhexyl, nonyl, isononyl, decyl, dodecyl, tridecyl, tetradecyl, pentadecyl, hexadecyl, heptadecyl and octadecyl.

The aryl group optionally having substituent(s) refers to a C₆-C₃₀ aryl group, such as phenyl, naphthyl, 2-methylphenyl, 3-methylphenyl, 4-methylphenyl, 4-vinylphenyl, 3-isopropylphenyl, 4-isopropylphenyl, isobutylphenyl, 4-butylphenyl, 4-hexylphenyl, 4-cyclohexylphenyl, 4-octylphenyl, 4-(2-ethylhexyl) phenyl, 4-octadecylphenyl, 2,3-dimethylphenyl, 2,4-dimethylphenyl, 2,5-dimethylphenyl, 2,6-dimethylphenyl, 3,4-dimethylphenyl, 3,5-dimethylphenyl and cyclohexylphenyl.

The aralkyl group optionally having substituent(s) refers to a C₇-C₂₀ aralkyl group, such as benzyl, diphenylmethyl, triphenylmethyl, phenethyl, styryl and cinnamyl.

In the alkoxy group optionally having substituent(s), the alkyl group is the same as defined above. That is, it may be, for example, methoxy, ethoxy, propoxy, butoxy, pentyloxy, etc. And, in the aryloxy group optionally having substituent(s), the aryl is the same as defined above. To be specific, it may be benzyloxy, phenoxy, benzoyloxy, etc.

In the alkoxycarbonyl group optionally having substituent(s), the alkyl group is the same as defined above. To be specific, it may be methoxycarbonyl, ethoxycarbonyl, propoxycarbonyl, etc.

In the definition of the substituents R2 to R4, the alkyl group optionally having substituent(s) refers to a C₁-C₆ linear or branched hydrocarbon, such as methyl, ethyl, propyl and t-butyl.

And, the alkenyl group optionally having substituent(s) preferably has 2 to 6 carbon atoms. It may be, for example, vinyl, aryl, 3-buten-1-yl, etc.

The alkoxycarbonyl group optionally having substituent(s) is the same as in R1. It may be, for example, methoxycarbonyl, ethoxycarbonyl, propoxycarbonyl, etc.

The phenyl group optionally having substituent(s) refers to a phenyl group substituted by alkyl, alkoxy or halogen.

In the definition of the substituents R5 and R6, the aryl group optionally having substituent(s) and the alkyl group optionally having substituent(s) are the same as defined in the substituent R1.

In the definition of the substituents Y and Z, the C₁-C₈ alkyl group or the C₆-C₃₀ aryl group optionally having substituent(s) is the same as defined in R1.

The cyanine dye represented by the formula 1 comprises pyrrole derivatives which are symmetrically joined by a conjugated double bonding group having odd number of carbon atoms. The number of carbon atoms of the conjugated double bonding group is an odd number, preferably 1, 3 or 5.

The present invention also relates to a multi-functional film for color compensation and near IR a bsorption comprising the cyanine dye represented by the formula 1 and a near IR absorbing dye.

When the cyanine dye represented by the formula 1, which has superior solubility and compatibility, is mixed along with a near IR absorbing dye to prepare a film, both of color compensation and near IR absorption capabilities can be attained, thereby simplifying manufacture process and reducing manufacture cost.

Preferably, the compound represented by the formula 1, which is used in the film for color compensation and the multi-functional film for color compensation and near IR absorption of the present invention, is a cyanine dye in which —A— is 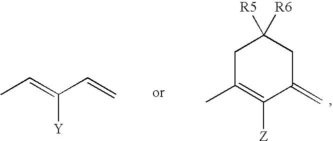
Y and Z are hydrogen atoms, R1 is a hydrogen atom, each of R2 and R4 is an alkyl group optionally having substituent(s) or an alkylcarbonyl group optionally having substituent(s), R5 and R6 are hydrogen atoms and X⁻ is perhalogenate or alkyl sulfate. More preferably, the compound represented by the formula 1 is one of the compounds represented by the formulas 1a to 1d below.

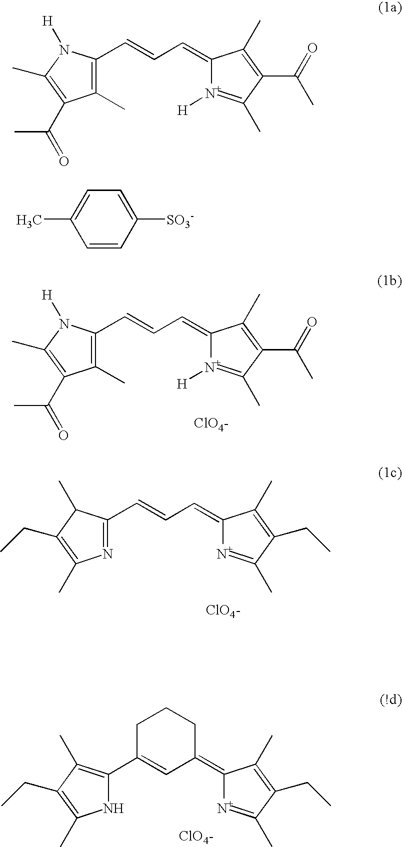

The near IR absorbing dye may be at least one selected from the group consisting of a diimmonium dye, a phthalocyanine dye, a naphthalocyanine dye and a metal-complex dye.

To be specific, the near IR absorbing dye may be at least one selected from the group consisting of a diimmonium dye represented by the formula 2 below, a phthalocyanine dye represented by the formula 3 below, a naphthalocyanine dye represented by the formula 4 and a metal-complex dye represented by the formula 5 or formula 6 below:

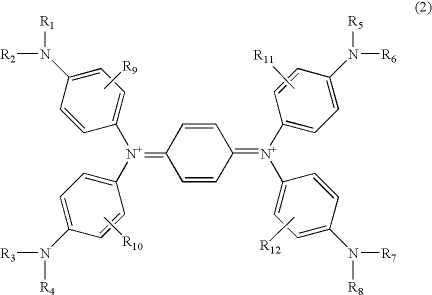

where

each of R1 to R12 is a hydrogen atom, a C₁-C₁₆ substituted or unsubstituted alkyl group or a C₆-C₃₀ substituted or unsubstituted aryl group;

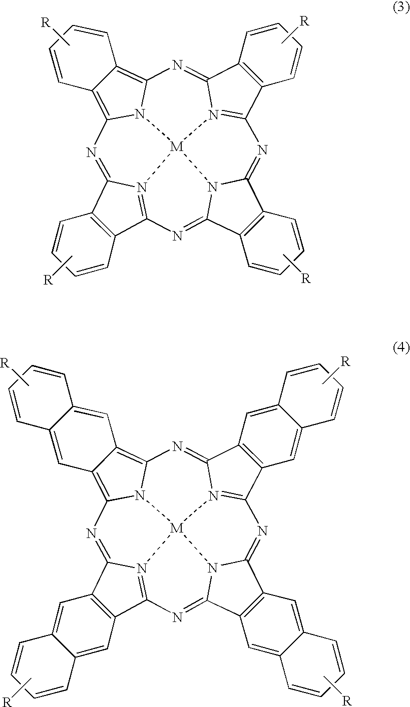

where

each of R is a hydrogen atom, a halogen atom, a substituted or unsubstituted alkyl group, a substituted or unsubstituted aryl group, a substituted or unsubstituted alkoxy group, a substituted or unsubstituted aryloxy group, a substituted or unsubstituted pentagonal ring having at least one nitrogen atom, in which the substituent may be a halogen atom, an alkylthio group, a C₁-C₅ alkoxy group, a C₆-C₁₀ aryloxy group or a C₁-C₁₆ alkylamino group;

M represents two hydrogen atoms, a divalent metal atom, a trivalent or tetravalent metal atom or an oxymetal;

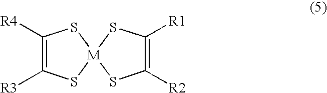

where

each of R1 to R4 is a hydrogen atom, a cyano group, a hydroxy group, a nitro group, an alkoxy group, an aryloxy group, an alkylthio group, a fluoroalkyl group, an acyl group, a carbamoyl group, an alkylaminocarbonyl group, an alkoxycarbonyl group, an aryloxycarbonyl group, a substituted or unsubstituted aryl group or a substituted or unsubstituted naphthyl group, in which the substituent may be a halogen atom, an alkylthio group, a C₁-C₅ alkoxy group, a C₆-C₁₀ aryloxy group or a C₁-C₁₆ alkylamino group;

M is nickel, platinum, palladium or copper; and

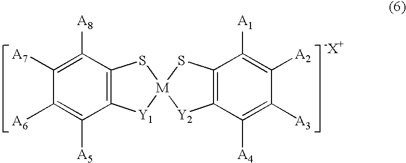

where

each of A1 to A8 is a hydrogen atom, a halogen atom, a nitro group, a cyano group, a thiocyanato group, a cyanato group, an acyl group, a carbamoyl group, an alkylaminocarbonyl group, an alkoxycarbonyl group, an aryloxycarbonyl group, a substituted or unsubstituted alkyl group, a substituted or unsubstituted aryl group, a substituted or unsubstituted alkoxy group, a substituted or unsubstituted aryloxy group, a substituted or unsubstituted alkylthio group, a substituted or unsubstituted arylthio group, a substituted or unsubstituted alkylamino group, a substituted or unsubstituted arylan amino group, a substituted or unsubstituted alkylcarbonylamino group or a substituted or unsubstituted arylcarbonylamino group, in which the substituent may be a halogen atom, a C₁-C₅ alkoxy group, a C₆-C₁₀ aryloxy group or a C₁-C₁₆ alkylamino group;

each of Y1 and Y2 is oxygen or sulfur;

X⁺ represents a quaternary ammonium group or a quaternary phosphonium group; and

M is nickel, platinum, palladium or copper.

The diimmonium cation represented by the formula 2 may bind with a monovalent or divalent organic acid anion or a monovalent or divalent inorganic acid anion to form a diimmonium dye.

Preferably, the monovalent organic acid anion may be an organic carboxylate, such as acetate, lactate, trifluoroacetate, propionte, benozate, oxalate, succinate and stearate; an organic sulfonate, such as methanesulfonate, toluenesulfonate, naphthalene monosulfonate, chlorobenzenesulfonate, nitrobenzenesulfonate, dodecylbenzenesulfonate, benzenesulfonate, ethanesulfonate and trifluoromethanesulfonate; or an organic borate, such as tetraphenylborate and butyltriphenylborate.

And, the divalent organic acid anion may be naphthalene-1,5-disulfonate, naphthalene-1,6-disulfonate, naphthalene disulfonate derivative, etc.

The monovalent inorganic acid anion may be a halogenate such as fluoride, chloride, bromide, iodide, thiocyanate, hexafluoroantimonate, perchlorate, periodate, nitrate, tetrafluoroborate, hexafluorophosphate, molybdate, tungstate, titanate, vanadate, phosphate and borate.

The film for color compensation of the present invention is manufactured by dissolving the cyanine dye represented by the formula 1 and a binder resin in an organic solvent to prepare a coating solution and coating the coating solution on a transparent substrate to a thickness of 1-20 μm.

The binder resin may be polyacryl, polyester, polyurethane, polycarbonate, polyamide, polystyrene, polyacrylonitrile or a copolymer thereof. The organic solvent may be toluene, xylene, propyl alcohol, isopropyl alcohol, ethyl acetate, dimethylformamide, acetone, tetrahydrofuran, methyl ethyl ketone, etc.

The film for color compensation of the present invention has the maximum transmittance in the range of 560-600 nm, thereby being capable of selectively shielding the neon light emitted from the PDP, and has a half bandwidth of 50 nm or smaller. When tested under high temperature and high temperature/high humidity conditions, more specifically when tested at 80° C. for 500 hours and at 60° C. and R.H. (relative humidity) 90% for 500 hours, the film for color compensation of the present invention shows transmittance deference before and after the test of 5% or smaller, in the visible region, particularly in 500-650 nm.

The multi-functional film for color compensation and near IR absorption comprising the dye and a near IR absorbing dye is manufactured in the same manner of the film for color compensation. The resultant film effectively shields the neon light generated in the region of 560-600 nm and absorbs near IR ray in the 800-1200 nm region, particularly in the 850-1100 nm region, to 20% or lower.

The present invention further relates to a PDP filter comprising the film for color compensation or the multi-functional film for color compensation and near IR absorption.

The PDP filter may be comprise an anti-reflection film (AR film), the film for color compensation or the multi-functional film for color compensation and near IR absorption and an electromagnetic interference shielding film (EMI film), etc.

Hereinbelow are given descriptions about manufacturing process of the film for color compensation of the present invention, manufacturing process of the multi-functional film for color compensation and near IR absorption and physical property (durability) evaluation results thereof.

<Manufacturing Process of Film for Color Compensation>

1. Preparation of coating solution: A cyanine dye represented by any one of formula 1a to formula 1d is mixed with 100 g of a binder resin solution obtained by dissolving 30 g of PMMA (polymethylmethacrylate) in 70 g of methyl ethyl ketone (MEK) to prepare a coating solution.

2. Coating: The coating solution is coated on a transparent substrate film to a wanted thickness (for example, 15 μm) and dried at 120° C. for 5 minutes to obtain a film for color compensation.

<Manufacturing Process of Multi-Functional Film for Color Compensation and Near IR Absorption>

1. Preparation of coating solution: A cyanine dye represented by any one of formula 1a to formula 1d, a first near IR absorbing dye, a second near IR absorbing dye and a color compensation dye are mixed with 100 g of a binder resin solution obtained by dissolving 30 g of PMMA or SAN in 70 g of methyl ethyl ketone (MEK) to prepare a coating solution.

2. Coating: The coating solution is coated on a transparent substrate film to a wanted thickness (for example, 15 μm) and dried at 120° C. for 5 minutes to obtain a film for color compensation.

### BRIEF DESCRIPTION OF THE DRAWINGS

FIG. 1 shows transmittance of the film for color compensation prepared in Example 1 before and after being tested at 80° C. for 500 hours.

FIG. 2 shows transmittance of the film for color compensation prepared in Example 1 before and after being tested at 60° C. and R.H. 90% for 500 hours.

FIG. 3 shows transmittance of the film for color compensation prepared in Example 2 before and after being tested at 80° C. for 500 hours.

FIG. 4 shows transmittance of the film for color compensation prepared in Example 2 before and after being tested at 60° C. and R.H. 90% for 500 hours.

FIG. 5 shows transmittance of the film for color compensation prepared in Example 3 before and after being tested at 80° C. for 500 hours.

FIG. 6 shows transmittance of the film for color compensation prepared in Example 3 before and after being tested at 60° C. and R.H. 90% for 500 hours.

FIG. 7 shows transmittance of the multi-functional film for color compensation and near IR absorption prepared in Example 4 before and after being tested at 80° C. for 500 hours.

FIG. 8 shows transmittance of the multi-functional film for color compensation and near IR absorption prepared in Example 4 before and after being tested at 60° C. and R.H. 90% for 500 hours.

FIG. 9 shows transmittance of the multi-functional film for color compensation and near IR absorption prepared in Example 5 before and after being tested at 80° C. for 500 hours.

FIG. 10 shows transmittance of the multi-functional film for color compensation and near IR absorption prepared in Example 5 before and after being tested at 60° C. and R.H. 90% for 500 hours.

FIG. 11 shows transmittance of the multi-functional film for color compensation and near IR absorption prepared in Example 6 before and after being tested at 80° C. for 500 hours.

FIG. 12 shows transmittance of the multi-functional film for color compensation and near IR absorption prepared in Example 6 before and after being tested at 60° C. and R.H. 90% for 500 hours.

FIG. 13 shows transmittance of the multi-functional film for color compensation and near IR absorption prepared in Example 7 before and after being tested at 80° C. for 500 hours.

FIG. 14 shows transmittance of the multi-functional film for color compensation and near IR absorption prepared in Example 7 before and after being tested at 60° C. and R.H. 90% for 500 hours.

### BEST MODES FOR CARRYING OUT THE INVENTION

Hereinafter, the present invention is further in detail through examples. However, the following examples are only for the understanding of the invention and the invention is not limited to or by them.

### Example 1

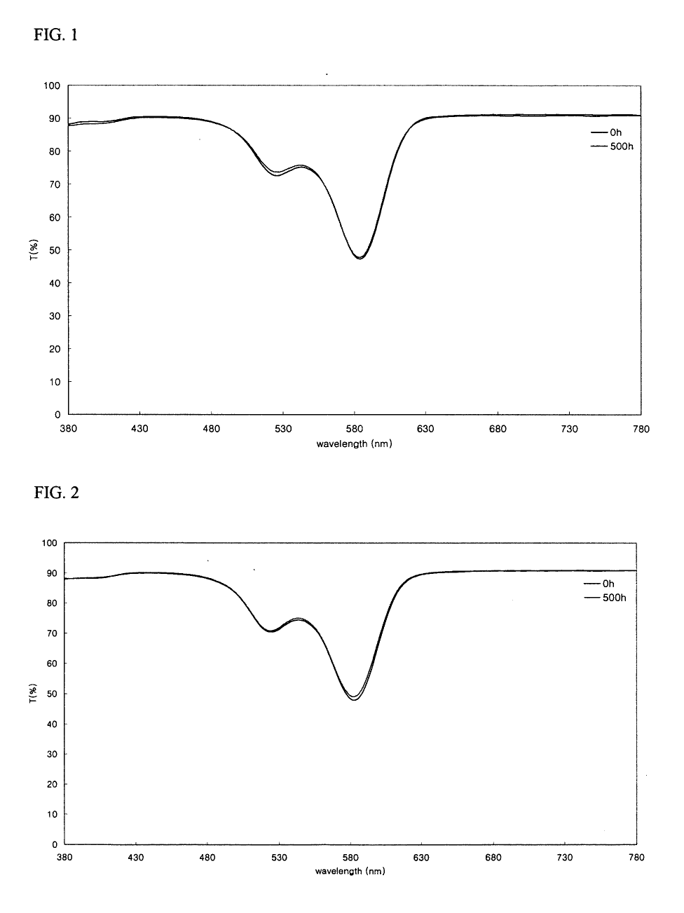

0.025 g of the compound represented by the formula 1a was mixed with 100 g of a binder resin solution obtained by dissolving 30 g of PMMA in 70 g of methyl ethyl ketone (MEK) for 30 minutes. The resultant solution was bar coated on a transparent PET film to obtain a film. The film was dried at 120° C. for 5 minutes. The resultant film for color compensation had a thickness of 15 μm and showed maximum absorbance at 584 nm. Transmittance was measured after keeping under high temperature condition (80° C.) and high temperature/high humidity condition (60° C., R.H. 90%) for 500 hours. Transmittance difference at 584 nm before and testing was 1.3% or smaller. The result is shown in FIG. 1 and FIG. 2.

### Example 2

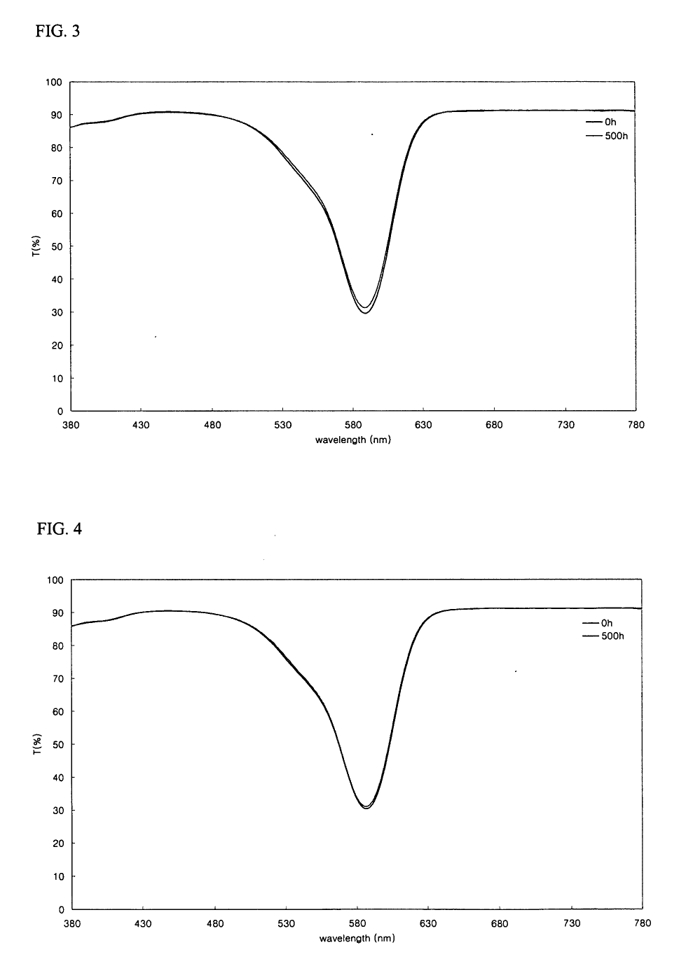

0.025 g of the compound represented by the formula 1c was mixed with 100 g of a binder resin solution obtained by dissolving 30 g of PMMA in 70 g of methyl ethyl ketone (MEK) for 30 minutes. The resultant solution was bar coated on a transparent PET film to obtain a film. The film was dried at 120° C. for 5 minutes. The resultant film for color compensation had a thickness of 15 μm and showed maximum absorbance at 588 nm. Transmittance was measured after keeping under high temperature condition (80° C.) and high temperature/high humidity condition (60° C., R.H. 90%) for 500 hours. Transmittance difference at 588 nm before and testing was 1.9% or smaller. The result is shown in FIG. 3 and FIG. 4.

### Example 3

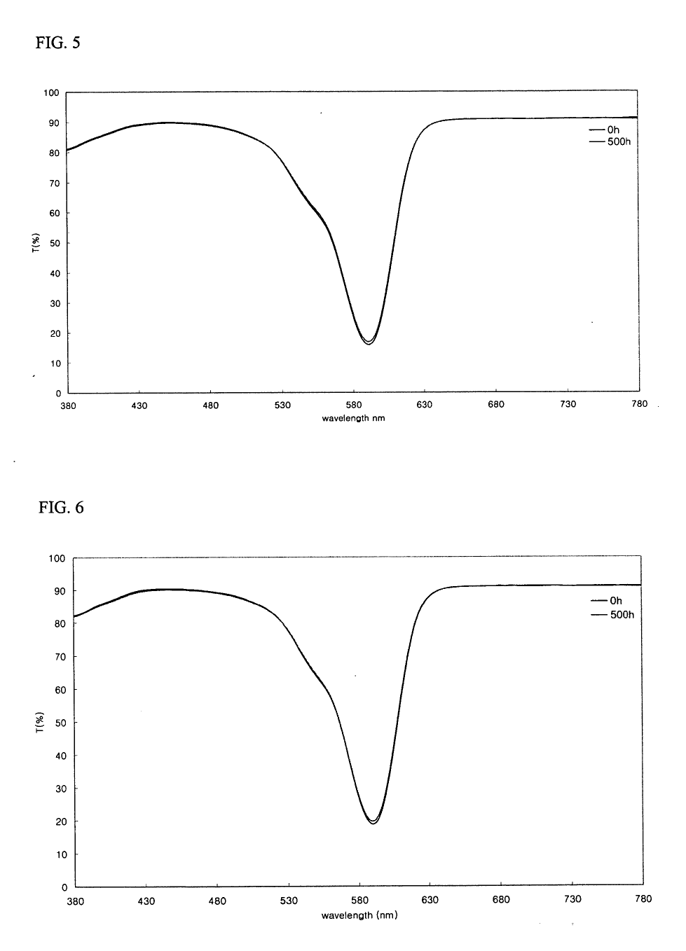

0.04 g of the compound represented by the formula 1d was mixed with 100 g of a binder resin solution obtained by dissolving 30 g of PMMA in 70 g of methyl ethyl ketone (MEK) for 30 minutes. The resultant solution was bar coated on a transparent PET film to obtain a film. The film was dried at 120° C. for 5 minutes. The resultant film for color compensation had a thickness of 15 μm and showed maximum absorbance at 590 nm. Transmittance was measured after keeping under high temperature condition (80° C.) and high temperature/high humidity condition (60° C., R.H. 90%) for 500 hours. Transmittance difference at 590 nm before and testing was 1.0% or smaller. The result is shown in FIG. 5 and FIG. 6.

### Example 4

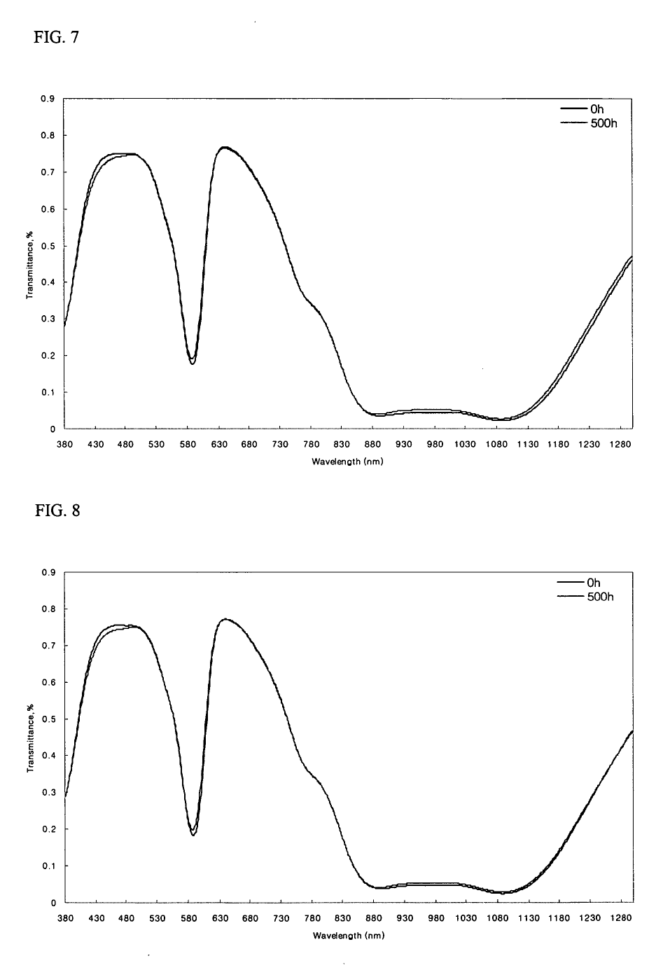

0.025 g of the cyanine dye represented by the formula 1c, 0.4 g of a diimmonium near IR absorbing dye (CIR1081, Japan Carlit) and 0.22 g of a phthalocyanine dye near IR absorbing dye (IR12, Japan Catalyst) were dissolved in 100 g of a binder resin solution obtained by dissolving 30 g of PMMA in 70 g of methyl ethyl ketone (MEK). The resultant solution was bar coated on a transparent PET film to obtain a film. The film was dried at 120° C. for 5 minutes. The resultant film for color compensation had a thickness of 17 μm and showed maximum absorbance at 588 nm in the visible region and a transmittance in the near IR region, particularly at 850 nm and 950 nm, of 8.8% and 4.7%, respectively. Transmittance was measured after keeping under high temperature condition (80° C.) and high temperature/high humidity condition (60° C., R.H. 90%) for 500 hours. Transmittance difference before and testing was 2.2% or smaller in the visible region (430-700 nm) and 0.2% and 0.8% or smaller in the near IR region (850 nm and 950 nm respectively). The result is shown in FIG. 7 (see Table 1) and FIG. 8 (see Table 2).

TABLE 1

| | Transmittance (%) | | | | | | |
|---|---|---|---|---|---|---|---|
| | 430 | | | | | | |
| | nm | 450 nm | 550 nm | 588 nm | 628 nm | 850 nm | 950 nm |
| Before | 70.3 | 74.3 | 54.7 | 17.6 | 74.5 | 8.8 | 4.4 |
| testing | | | | | | | |
| After | 68.1 | 72.6 | 55.1 | 19.1 | 74.4 | 8.8 | 5.2 |
| testing | | | | | | | |

TABLE 2

| | Transmittance (%) | | | | | | |
|---|---|---|---|---|---|---|---|
| | 430 | | | | | | |
| | nm | 450 nm | 550 nm | 588 nm | 628 nm | 850 nm | 950 nm |
| Before | 70.8 | 74.8 | 55.3 | 18.2 | 75.0 | 9.1 | 4.7 |
| testing | | | | | | | |
| After | 69.0 | 73.3 | 55.3 | 19.9 | 75.1 | 9.3 | 5.3 |
| testing | | | | | | | |

### Example 5

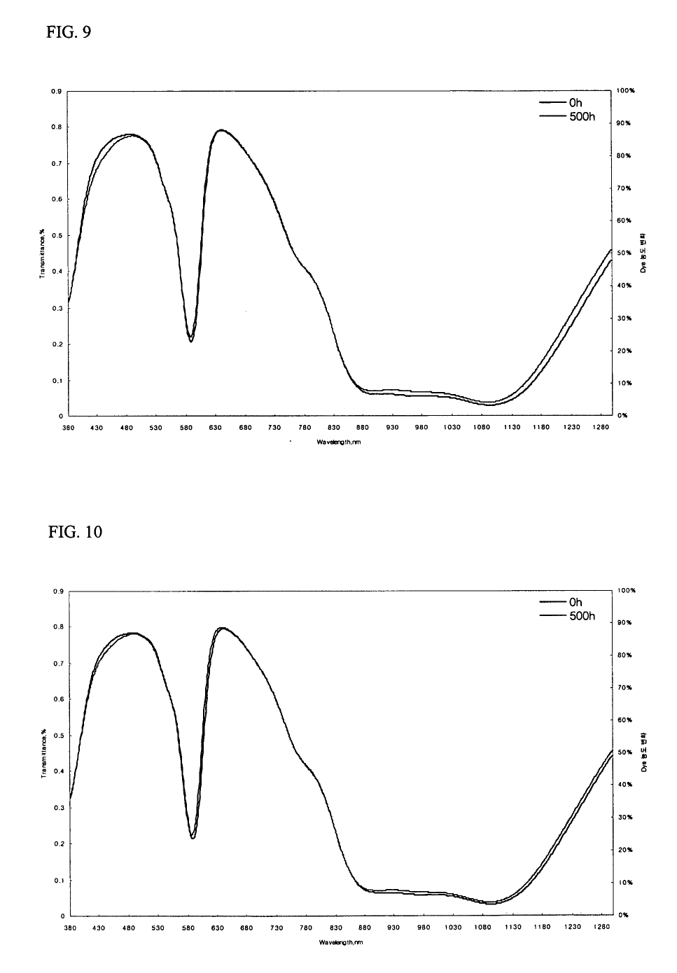

0.04 g of the cyanine dye represented by the formula 1d, 0.47 g of a diimmonium near IR absorbing dye (CIR1085, Japan Carlit) and 0.017 g of a phthalocyanine dye near IR absorbing dye (IR12, Japan Catalyst) were dissolved in 100 g of a binder resin solution obtained by dissolving 30 g of PMMA in 70 g of methyl ethyl ketone (MEK). The resultant solution was bar coated on a transparent PET film to obtain a film. The film was dried at 120° C. for 5 minutes. The resultant film for color compensation had a thickness of 17 μm and showed maximum absorbance at 589 μm in the visible region and a transmittance in the near IR region, particularly at 850 nm and 950 nm, of 13.3% and 5.7%, respectively. Transmittance was measured after keeping under high temperature condition (80° C.) and high temperature/high humidity condition (60° C., R.H. 90%) for 500 hours. Transmittance difference before and testing was 3% or smaller in the visible region (430-700 nm) and 0.2% and 1.3% or smaller in the near IR region (850 nm and 950 nm respectively). The result is shown in FIG. 9 (see Table 3) and FIG. 10 (see Table 4).

TABLE 3

| | Transmittance (%) | | | | | | |
|---|---|---|---|---|---|---|---|
| | 430 | | | | | | |
| | nm | 450 nm | 550 nm | 590 nm | 628 nm | 850 nm | 950 nm |
| Before | 71.1 | 75.6 | 60.7 | 20.6 | 76.7 | 13.3 | 5.7 |
| testing | | | | | | | |
| After | 68.1 | 73.2 | 60.8 | 22.1 | 77.3 | 13.5 | 7.0 |
| testing | | | | | | | |

TABLE 4

| | Transmittance (%) | | | | | | |
|---|---|---|---|---|---|---|---|
| | 430 | | | | | | |
| | nm | 450 nm | 550 nm | 590 nm | 628 nm | 850 nm | 950 nm |
| Before | 71.4 | 75.8 | 61.3 | 21.4 | 77.1 | 13.9 | 6.1 |
| testing | | | | | | | |
| After | 69.9 | 74.5 | 61.2 | 22.8 | 78.5 | 13.9 | 6.9 |
| testing | | | | | | | |

### Example 6

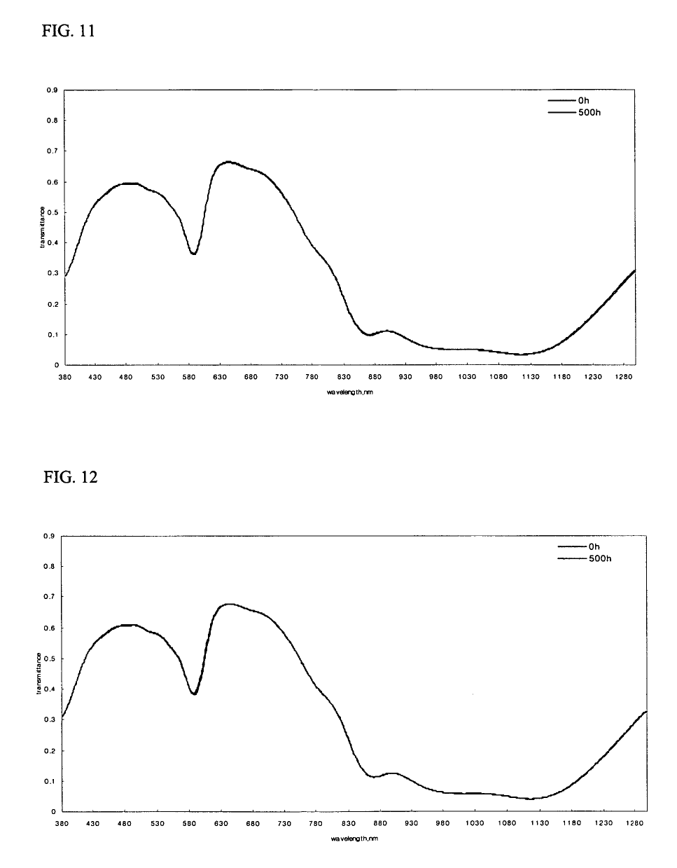

0.051 g of the cyanine dye represented by the formula 1c, 0.54 g of a diimmonium near IR absorbing dye (CIR1081, Japan Carlit), 0.32 g of a phthalocyanine dye near IR absorbing dye (IR12, Japan Catalyst) and a color compensation dye were dissolved in 100 g of a binder resin solution obtained by dissolving 30 g of SAN in 70 g of methyl ethyl ketone (MEK). The resultant solution was bar coated on a transparent PET film to obtain a film. The film was dried at 120° C. for 5 minutes. The resultant film for color compensation had a thickness of 15 μm and showed maximum absorbance at 591 nm in the visible region and a transmittance in the near IR region, particularly at 850 nm and 950 nm, of 15.2% and 7.2%, respectively. Transmittance was measured after keeping under high temperature condition (80° C.) and high temperature/high humidity condition (60° C., R.H. 90%) for 500 hours. Transmittance difference before and testing was 1.0% or smaller in the visible region (430-700 nm) and 0.4% and 0.3% or smaller in the near IR region (850 nm and 950 nm respectively). The result is shown in FIG. 11 (see Table 5) and FIG. 12 (see Table 6).

TABLE 5

| | Transmittance (%) | | | | | | |
|---|---|---|---|---|---|---|---|
| | 430 | | | | | | |
| | nm | 450 nm | 550 nm | 591 nm | 628 nm | 850 nm | 950 nm |
| Before | 61.0 | 64.5 | 57.9 | 37.7 | 71.7 | 15.2 | 7.2 |
| testing | | | | | | | |
| After | 60.4 | 63.9 | 57.6 | 38.0 | 71.4 | 15.7 | 7.5 |
| testing | | | | | | | |

TABLE 6

| | Transmittance (%) | | | | | | |
|---|---|---|---|---|---|---|---|
| | | 450 | | | | | |
| | 430 nm | nm | 550 nm | 591 nm | 628 nm | 850 nm | 950 nm |
| Before | 59.6 | 63.7 | 59.7 | 42.3 | 73.0 | 16.2 | 8.7 |
| testing | | | | | | | |
| After | 5936 | 63.4 | 59.6 | 43.1 | 73.3 | 16.2 | 8.7 |
| testing | | | | | | | |

### Example 7

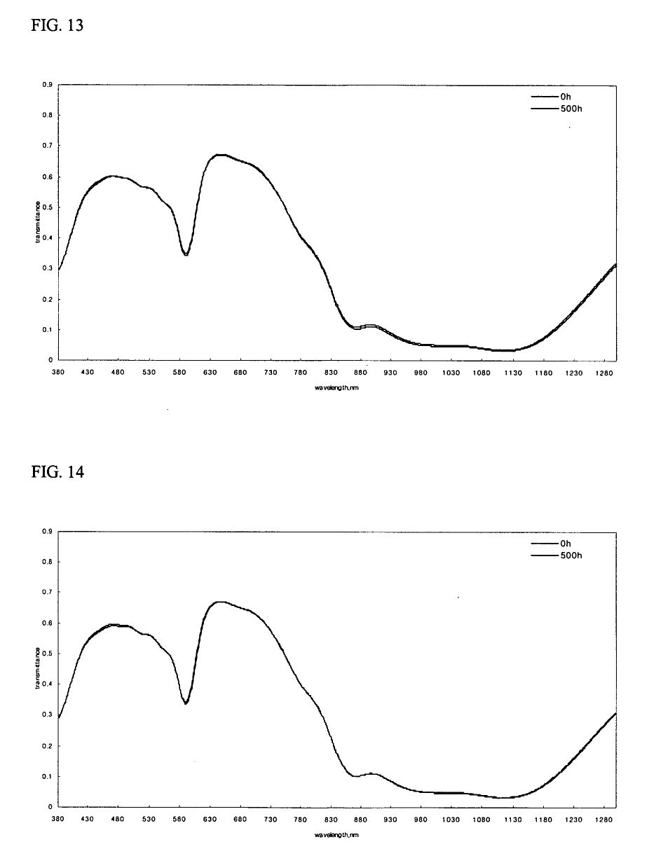

0.04 g of the cyanine dye represented by the formula 1d, 0.54 g of a diimmonium near IR absorbing dye (CIR1081, Japan Carlit) and 0.32 g of a phthalocyanine dye near IR absorbing dye (IR12, Japan Catalyst) were dissolved in 100 g of a binder resin solution obtained by dissolving 30 g of SAN in 70 g of methyl ethyl ketone (MEK). The resultant solution was bar coated on a transparent PET film to obtain a film. The film was dried at 120° C. for 5 minutes. The resultant film for color compensation had a thickness of 14 μm and showed maximum absorbance at 591 nm in the visible region and a transmittance in the near IR region, particularly at 850 nm and 950 nm, of 15.2% and 7.2%, respectively. Transmittance was measured after keeping under high temperature condition (80° C.) and high temperature/high humidity condition (60° C., R.H. 90%) for 500 hours. Transmittance difference before and testing was 1.0% or smaller in the visible region (430-700 nm) and 0.8% and 0.6% or smaller in the near IR region (850 nm and 950 nm respectively). The result is shown in FIG. 13 (see Table 7) and FIG. 14 (see Table 8).

TABLE 7

| | Transmittance (%) | | | | | | |
|---|---|---|---|---|---|---|---|
| | 430 | | | | | | |
| | nm | 450 nm | 550 nm | 591 nm | 628 nm | 850 nm | 950 nm |
| Before | 61.1 | 64.5 | 57.9 | 37.7 | 71.7 | 15.2 | 7.2 |
| testing | | | | | | | |
| After | 60.4 | 64.0 | 57.8 | 38.5 | 71.6 | 16.2 | 7.8 |
| testing | | | | | | | |

TABLE 8

| | Transmittance (%) | | | | | | |
|---|---|---|---|---|---|---|---|
| | 430 | | | | | | |
| | nm | 450 nm | 550 nm | 591 nm | 628 nm | 850 nm | 950 nm |
| Before | 59.7 | 63.4 | 57.4 | 37.2 | 71.2 | 15.5 | 7.3 |
| testing | | | | | | | |
| After | 59.2 | 62.8 | 57.5 | 37.7 | 71.5 | 15.3 | 7.4 |
| testing | | | | | | | |

### INDUSTRIAL APPLICABILITY

As described above, the film for color compensation of the present invention has maximum transmittance in the 560-600 nm region and a half bandwidth of 50 nm or smaller. The film for color compensation can compensate for decrease of color purity of red spectrum caused by the specific orange spectrum emitted from the PDP. Also, it experiences less transmittance change under high temperature and high temperature/high humidity condition, thereby offering good durability, has superior solubility and compatibility, thereby being advantageous in manufacturing a multi-functional film having the capability of color compensation and near IR absorption by using a near IR absorbing dye, can simplify manufacture process and can reduce manufacture cost.

While the present invention has been described in detail with reference to the preferred embodiments, those skilled in the art will appreciate that various modifications and substitutions can be made thereto without departing from the spirit and scope of the present invention as set forth in the appended claims.

1. A film for color compensation for a PDP filter comprising the cyanine dye represented by the following formula 1: 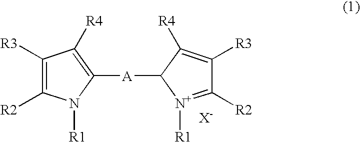
where
—A— represents a conjugated double bonding group having odd number of carbon atoms;
R1 is a hydrogen atom, an alkyl group optionally having substituent(s), an aryl group optionally having substituent(s), an aralkyl group optionally having substituent(s), an alkoxy group optionally having substituent(s), an aryloxy group optionally having substituent(s) or an alkoxycarbonyl group optionally having substituent(s);
each of R2-R4 is a hydrogen atom, an alkyl group optionally having substituent(s), an alkenyl group optionally having substituent(s), an alkoxycarbonyl group optionally having substituent(s), a phenyl group optionally having substituent(s), a halogen atom, a nitro group, a cyano group, a hydroxy group, an amino group, a sulfonate group, a sulfonyl group or a carboxyl group; and
X⁻ is a halide, a perhalogenate, a fluoro complex anion, an alkyl sulfate or a sulfonate.

2. The film for color compensation of claim 1 in which -A- represents 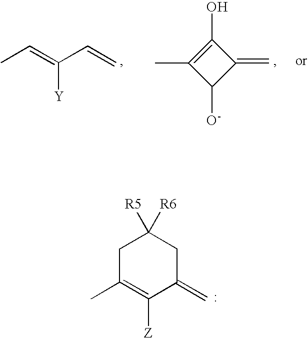
where
each of R5 and R6 is a hydrogen atom, a halogen atom, a cyano group, an aryl group optionally having substituent(s), a diphenylamino group or an alkyl group optionally having substituent(s); and
Y and Z are hydrogen atoms, halogen atoms, cyano groups, C₁-C₈ alkyl groups optionally having substituent(s) or C₆-C₃₀ aryl groups.

3. The film for color compensation of claim 2 in which —A— is 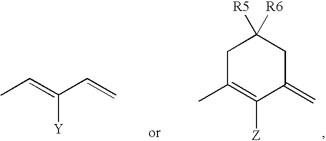
Y and Z are hydrogen atoms, R1 is a hydrogen atom, each of R2 to R4 is an alkyl group optionally having substituent(s) or an alkylcarbonyl group optionally having substituent(s), R5 and R6 are hydrogen atoms and X⁻ is a perhalogenate or an alkyl sulfate.

4. The film for color compensation of claim 3 in which the cyanine dye represented by the formula 1 is selected from the group consisting of the compounds represented by the following formulas 1a to 1d:

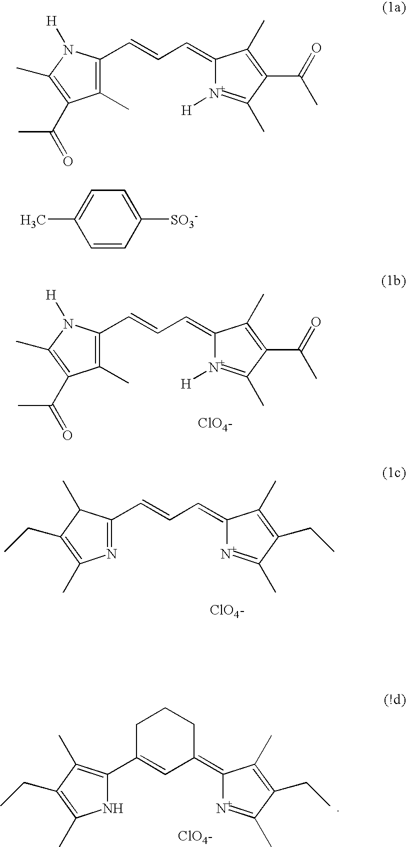

5. A multi-functional film for color compensation and near IR absorption for a PDP filter comprising a near IR absorbing dye and the cyanine dye represented by the formula 1: 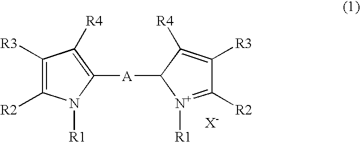
where
—A— represents a conjugated double bonding group having odd number of carbon atoms;
R1 is a hydrogen atom, an alkyl group optionally having substituent(s), an aryl group optionally having substituent(s), an aralkyl group optionally having substituent(s), an alkoxy group optionally having substituent(s), an aryloxy group optionally having substituent(s) or an alkoxycarbonyl group optionally having substituent(s);
each of R2-R4 is a hydrogen atom, an alkyl group optionally having substituent(s), an alkenyl group optionally having substituent(s), an alkoxycarbonyl group optionally having substituent(s), a phenyl group optionally having substituent(s), a halogen atom, a nitro group, a cyano group, a hydroxy group, an amino group, a sulfonate group, a sulfonyl group or a carboxyl group; and
X⁻ is a halide, a perhalogenate, a fluoro complex anion, an alkyl sulfate or a sulfonate.

6. The multi-functional film for color compensation and near IR absorption in accordance with 5 in which the near IR absorbing dye is at least one selected from the group consisting of a diimmonium dye, a phthalocyanine dye, a naphthalocyanine dye and a metal-complex dye.

7. (canceled)

8. A PDP filter comprising the film for color compensation in accordance with claim 1.

9. A PDP filter comprising the multi-functional film in accordance with claim 5.
